(19) United States
(12) Patent Application Publication
(10) Pub. No.: US 2004/0109376 A1
(43) Pub. Date: Jun. 10, 2004

(54) Method for detecting logical address of flash memory

(76) Inventor: Jin-Shin Lin, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/314,123

(22) Filed: Dec. 9, 2002

(51) Int. Cl. G11C 5/06; G11C 8/00

(52) U.S. Cl. 365/230.03; 365/63

(57) ABSTRACT

The present invention is to provide a method for detecting the logical address of the flash memory. At the beginning of power-on a system, the present invention is to construct a scaled factor logical/physical address mapping table (AMT) which is using a zone as an unit. The present invention utilizes the address mapping table to obtain a physical zone corresponding to the logical address and then sequentially search each block of the physical zone until to obtain the physical address corresponding to the awaited-searching logical address. Hence, the present invention can obtain an effectively balance between the process speed and the space. The present invention does not occupy too much space on the premise of keeping fast processing speed.

### BACKGROUND OF THE INVENTION

1. Field of the Invention

The present invention generally relates to a method for detecting the logical address of the flash memory, and more particularly relates to utilize a plurality of blocks as a zone and to use the zone as an unit to construct the physical/logical address mapping table (AMT) or the look-up table so as to detect the logical address via the address mapping table.

2. Description of the Prior Art

According to the operation theorem of the memory, when the central processing unit (CPU) uses the memory as its data storage region, the calculating result and the data are stored herein. If the program needs to use the data or the calculating result therein, the data or the calculating result can be accessed from the storage region. As storing and reading the data, the central processing unit will define the required data with a position of the memory, the central processing unit sends the address to the memory via the position bus and then the data will transfers the corresponding data to the correct address. The reading time is the most important thing for the memory; from the central processing unit commanding the order to obtain the address data, transferring the data to the central processing unit after the memory responding, and then until the central processing unit actually receiving the data; wherein the spending time of the mentioned procedure is the accessing time of the memory.

However, in the flash memory, several Kilo-bytes composes a block as an unit to execute the storage and the reading of the data, wherein each data-accessing block provides with a physical address for presenting the space sequence of the flash memory, such as the position of the physical address of the static random access memory (SRAM). Simultaneously, each block records the logical address indicated by the flash file system, such as shown in the FIG. 1A, and content in each physical address would provide with a corresponding logical address. However, the mechanism of the flash memory, the data accessing of the file system requires the physical address and the logical address as a non-linear corresponding relation, which can not infer the position of the logical address from the physical address. Prior technology usually provides two methods for obtaining the corresponding logical address.

The first method is constructing a logical/physical address mapping table at the beginning of power-on the system, wherein the logical/physical address mapping table is recording the corresponding relation between the logical address and the physical address and is devised a plurality of static random access memory (SRAM) therein to store and record the logical/physical address mapping table. Referring to the FIG. 1, to construct the address mapping table is mainly used the arrangement sequence of the logical address and then to fill the corresponding physical address into the content of the address mapping table. Because the original logical addresses are irregularly arranged, so the original logical addresses need to sort from beginning to end to construct an address mapping table, such as shown in the FIG. 1B, and to store the address mapping table in the SRAM. Even the obverse physical/logical address mapping table only construct partial portion to save the capacities of the SRAM, it also needs to sort from beginning to end from the logical address of the flash memory. The file system will provide an awaited-searching logical address at the data accessing and utilizes the software to search the address mapping table in the SRAM so as to constantly obtain a physical address corresponding to the logical address. Although, the method using the address mapping table to search the logical address can provide with advantages of the short address transferring time and the fast processing speed, it requires huge amount of the SRAM to record all address corresponding relation and it occupies huge space. And may be unlimited required SRAM for the bigger and bigger flash size. Moreover, the recent trend is to integrate different functions in one single system chip, which the amount of the SRAM is fixed, so it cannot accord to requirement to increase the amount of the SRAM and causes the limitation of the application.

Another method is to infer the physical address from the logical address without the design of the SRAM or constructing any address mapping table, when it requires to find the corresponding logical address to the physical address, it only needs to utilize the software program to start the searching from the beginning of the memory until to find the required logical address in the memory. The method without the design of the SRAM does not occupy the space, but its searching time is too low because the searching is from the beginning of the memory until to find the required logical address in the memory, so the speed of accessing data in the memory is very slow.

Obviously, the main spirit of the present invention is to obtain an effective balance in two kinds of the transferring method between the physical address and the logical address mentioned above, the present invention can simultaneously combine the problem of the speed and the space to effectively enhance the access ability of the data, and then some disadvantages of well-known technology are overcome.

### SUMMARY OF THE INVENTION

The primary object of the present invention is to provide a method for detecting the logical address of the flash memory, which is using a zone as an unit to construct a scaled factor logical/physical address mapping table and to obtain the zone address via the logical/physical address mapping table so as to search the corresponding logical address to the physical address, so the present invention can achieve the enhancement of the speed with the limited investment of memory.

Another object of the present invention is to provide a method for detecting the logical address of the flash memory, which utilizes the adjusting type random access memory so as to simultaneously enhance the processing speed of the semiconductor disk device under the consideration of not increasing too much space.

In order to achieve previous objects, the present invention sets a plurality of blocks of the flash memory as a zone for using as an unit to construct a scaled factor address mapping table (AMT) via a relation between a physical address and its corresponding logical address at the beginning of turning-on a system and to store the scaled factor address mapping table in a random access memory (RAM). When the system is executing the data accessing, an awaited-searching logical address will be provided to the random access memory, a corresponding physical zone address is obtained from the scaled factor address mapping table by the random access memory to accord to the awaited-searching logical address; and then to search each the block of the physical zone until to obtain the physical address corresponding to the awaited-searching logical address.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1a and FIG. 1b are the schematic representation of the relation between the physical address and the logical address of the memory and the schematic representation of the logical/physical address mapping table (AMT) constructed by the relation, in accordance with the prior technology;

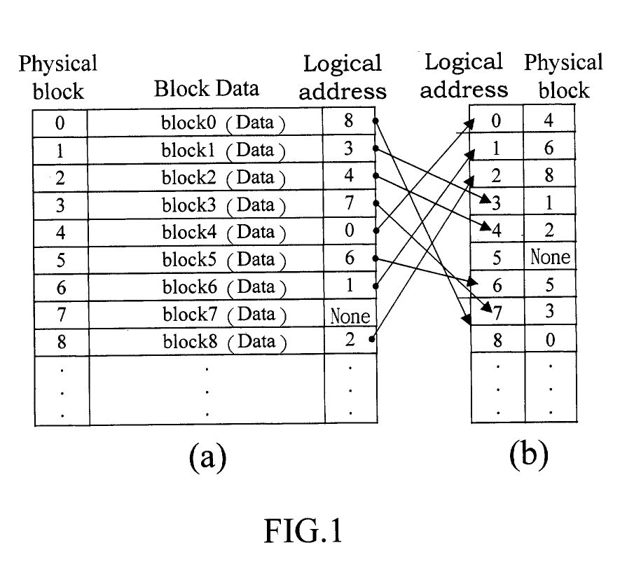

FIG. 2a and FIG. 2b are the schematic representation of the relation between the physical zone and the logical address of the memory and the schematic representation of the scaled factor logical/physical address mapping table (AMT) constructed by the relation, in accordance with the present invention;

FIG. 3 is a schematic representation of executing the disk rearranging step in the open system, in accordance with the present invention; and

FIG. 4 is a schematic representation of the architecture for detecting the logical address, in accordance with the present invention; and

FIG. 5 is a schematic representation of the flow chart for detecting the logical address, in accordance with the present invention.

### DESCRIPTION OF THE PREFERRED EMBODIMENT

The present invention utilizes a plurality of blocks as a zone to copy and construct an address mapping table (AMT), such as the logical address/zone logical address mapping table, and to match the characteristic of continuously reading of the random access memory to search the address mapping table of the random access memory to obtain the physical zone and following to search the corresponding logical address to the physical address in the zone.

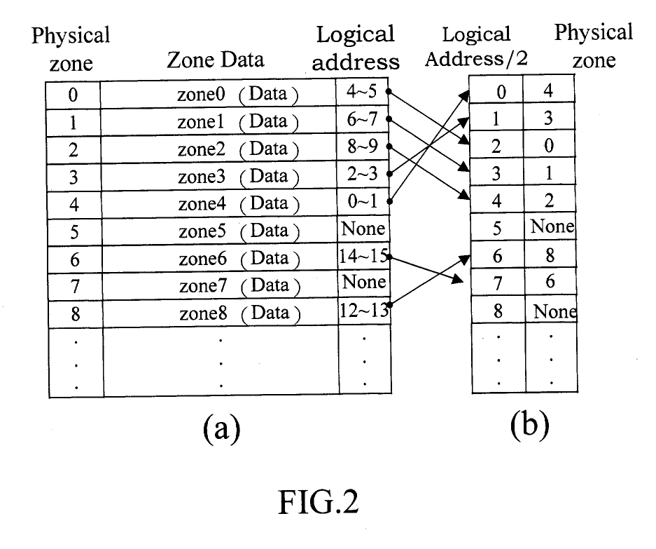

When the data storing and the data reading is executed in the flash memory, each data-accessing block provides with a physical address to present the position of the real physical memory in the memory. The present invention sets N blocks as a zone, and each zone provides with a physical zone position and its corresponding logical address, such as shown in the FIG. 2a, the corresponding relation between the physical zone and the logical address is non-linear. When the file system is executed the initialization, a scaled factor logical/physical address mapping table is copied and constructed according to the relation table of the FIG. 2a. At the same time, referring to the FIG. 2b, after constructing the scaled factor logical/physical mapping table, the scaled factor logical/physical mapping table is immediately stored in the static random access memory (SRAM) for providing the system to search awaited logical address. Owing to the address mapping table is constructed by using the zone as an unit, so the scaled factor logical/physical mapping table does not need to occupy too much storage space so as can decrease the use of the amount of the static random access memory (SRAM).

Wherein, the zone composed of N blocks, wherein the value N is 2′. In another word, the zone composes of 2′ blocks. It is better that the value n is at least 6.

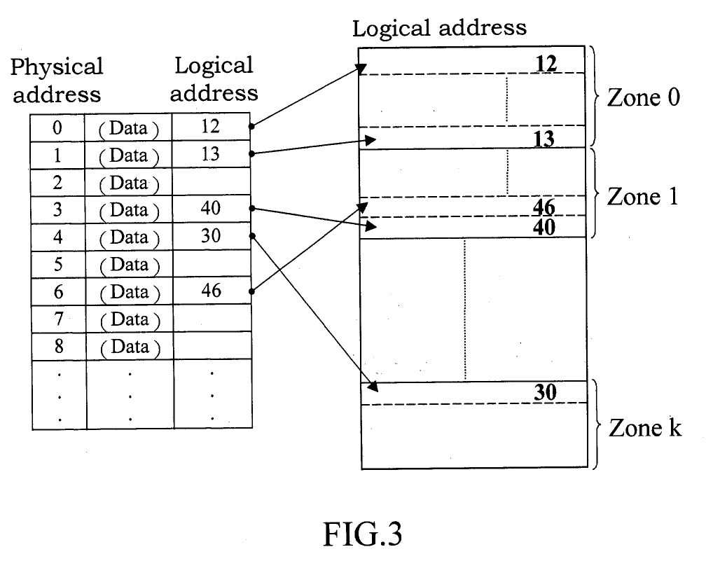

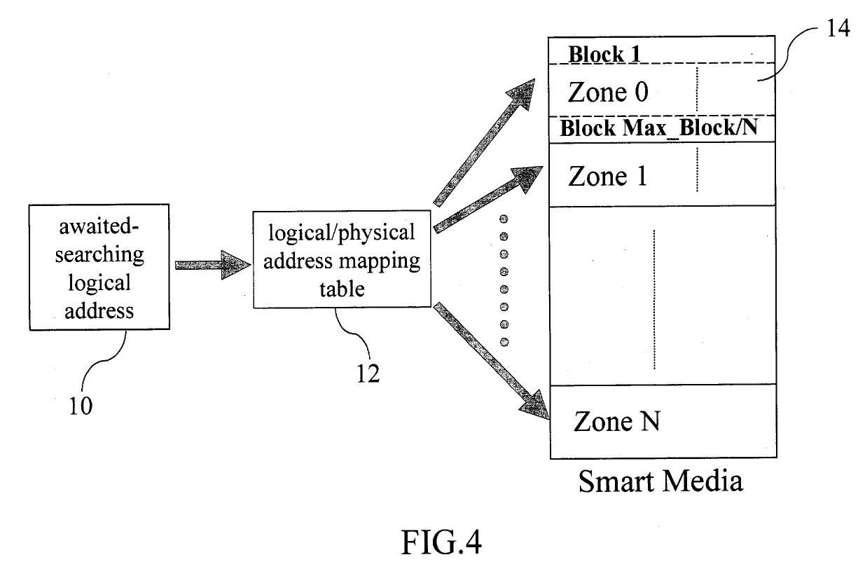

At the beginning of power-on the system, if the system is an open system, such as the removable flash memory disk, which may be accessed by other system, the corresponding relation of the logical/physical address may be irregularly distributed and needs to execute the disk rearranging process, referring to the FIG. 3. The disk zones with similar logical address are moved in the same zone. Such as shown in the figure, disk zones 10˜19 are classified the same Zone 0, disk zones 40˜49 are classified the Zone 1, disk zones 30˜39 are classified the Zone k, disk zones with similar logical address are moved in the same zone, such as the disk zone 12 and 13 are moved in the Zone 0, the disk zone 40 and 46 are moved in the Zone 1, the disk zone 30 is moved in the Zone k. Even the used removable flash memory disk is moved into other system for accessing, owing to the logical/physical address does not need any rule, so it can maintain the compatibility. If the system is a close system (the flash memory is fixed in the system), using the present invention method at the beginning can omit the rearranging step. Following, the system according to the size of the SRAM of the system constructs a scaled factor logical/physical address mapping table via the relation between the physical zone address and its corresponding logical address and to store the scaled factor logical/physical address mapping table in the static random access memory, such as shown in the FIG. 2b. Referring to the FIG. 4, at this time, according to the partial data of the awaited-searching logical address, a corresponding physical zone 14, such as the Zone 0, can be obtained from the logical/physical address mapping table 12 built-in-in the static random access memory. Following, after obtaining the physical zone 14, each block of the physical zone 14 of the Zone 0 is searched until to obtain the physical address corresponding to the logical address.

Besides, the present invention limits a new data in the same zone when said flash memory is writing or renewing data, and if the zone does not provide enough space, the original data of the zone and the new data will entirely copy to another zone in order to match the principle of the uniformly reading/writing.

Now, the principle of the present is dentally described in the forgoing. The following description will use an embodiment taken in conjunction with the flow chart to certificate the function and the effect of the semiconductor disk device mentioned above so as to enable any person skilled in the art to carry out the invention via the description of the following embodiment.

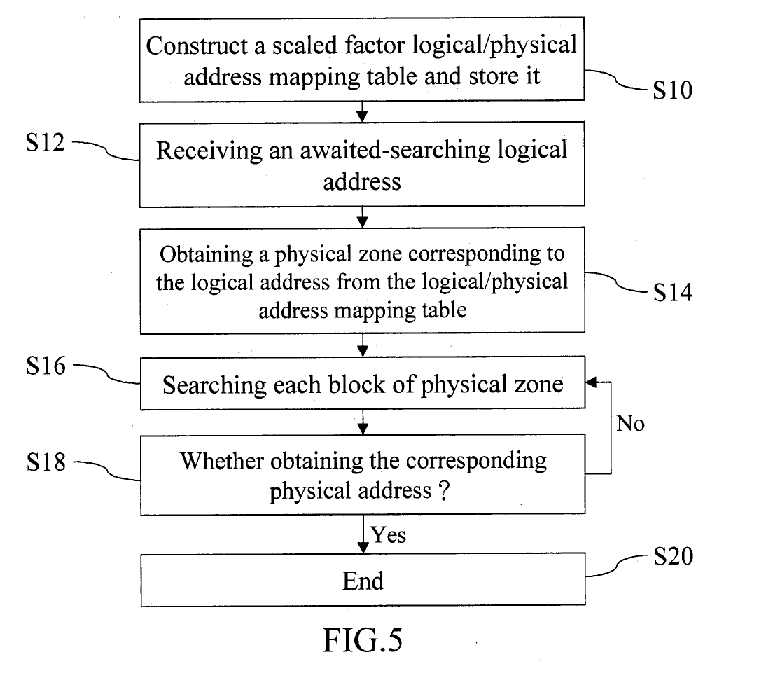

FIG. 5 is a schematic representation of the flow chart for detecting the logical address in accordance with the present invention. Such as shown in the FIG. 5, the method for detecting the logical address comprises the following steps. First, such as shown in the step S10, the present invention uses the forgoing method to construct a scaled factor logical/physical address mapping table (AMT) via a relation between a physical zone address and its corresponding logical address at the beginning of turning-on a system and to store the scaled factor address mapping table in a random access memory (RAM)

When the system is transferring an awaited-searching logical address to the random access memory, such as shown in the step S12, and after the random access memory is receiving the awaited-searching logical address signal, the system accords to the awaited-searching logical address signal to obtain a physical zone corresponding to the logical address from the logical/physical address mapping table, such as shown in the step S14. After obtaining the physical zone, the system is sequentially from top to down searching each block of the physical zone, such as shown in the step S16. The system compares and judges whether obtaining the corresponding physical address, as shown in the step S18, if the corresponding physical address is obtained, the searching simultaneously stops, such as shown in the step S20 to terminate the entire searching. If the corresponding physical address is not obtained, the step S16 is continuously executed until to obtain the corresponding physical address of the physical zone.

Owing to the scaled factor logical/physical address mapping table of the present invention is using the zone as an unit, so it is only partial address relation and it does not need to occupy too much random access memory. Moreover, the present invention firstly finds the physical zone corresponding to the logical address to search a smaller rang of the physical zone, so the processing speed is faster than the prior art. The present invention utilizes the zone concept to match the use of a few amount of the random access memory so as to simultaneously enhance the process speed of the semiconductor disk device (flash memory) without increasing too much space. The present invention can obtain an effective balance under the consideration of the speed and the space so as to combine the advantages of the fast processing speed and the occupied-free space to effectively enhance the ability of accessing the data.

Of course, it is to be understood that the invention described herein need not be limited to these disclosed embodiments. Various modification and similar changes are still possible within the spirit of this invention. In this way, all such variations and modifications are included within the intended scope of the invention and the scope of this invention should be defined by the appended claims.

What is claimed is:

1. A method for detecting a logical address of a flash memory, said method comprising following steps:
setting a plurality of blocks of said flash memory as a zone for using as an unit to construct a scaled factor address mapping table (AMT) via a relation between a zone address and its corresponding logical address at the beginning of turning-on a system and to store said scaled factor address mapping table in a random access memory (RAM);
obtaining a corresponding physical zone address from said scaled factor address mapping table by said random access memory to accord to said awaited-searching logical address when said system is transferring an awaited-searching logical address to said random access memory; and
searching each said block of said physical zone until to obtain the physical address corresponding to said awaited-searching logical address.

2. The method for detecting a logical address of a flash memory according to claim 1, wherein said random access memory is a static random access memory (SRAM)

3. The method for detecting a logical address of a flash memory according to claim 1, wherein a new data is limited in the same zone when said flash memory is writing or renewing data.

4. The method for detecting a logical address of a flash memory according to claim 3, if said zone does not provide enough space, the original data of said zone and the new data will entirely copy to another zone.

5. The method for detecting a logical address of a flash memory according to claim 1, wherein said zone is composed of 2′ blocks.

6. The method for detecting a logical address of a flash memory according to claim 5, wherein said value n is at least 6.

7. The method for detecting a logical address of a flash memory according to claim 1, wherein said scaled factor address mapping table is a logical zone address/physical address mapping table.
